(19) United States
(12) Patent Application Publication
(10) Pub. No.: US 2002/0072010 A1
(43) Pub. Date: Jun. 13, 2002

(54) Method of manufacturing dielectric layer for use in phase change type optical disk

(76) Inventor: Masayuki Kubogata, Tokyo (JP)

Correspondence Address: MCGINN & GIBB, PLLC, 8321 OLD COURTHOUSE ROAD, SUITE 200, VIENNA, VA, 22182-3817, US

(21) Appl. No.: 09/522,607

(22) Filed: Mar. 10, 2000

(30) Foreign Application Priority Data
Oct. 3, 1999 (JP) 63311/1999

(51) Int. Cl. G11B 7/24; C23C 14/08; C23C 14/10; C23C 14/54

(52) U.S. Cl. 430/270.13; 430/945; 428/64.5; 369/275.5; 369/275.2; 204/192.22; 204/192.23

(57) ABSTRACT

In a method of manufacturing a dielectric layer of ZnS—SiO₂ for use in a phase change type optical disk, a target, which is sintered with mixture of ZnS and SiO₂, is prepared. The dielectric layer is deposited by the use of a sputtering method in mixed atmosphere of argon gas, oxygen gas, and hydrogen gas. The deposition is carried out such that formation of dangling bonds is suppressed.

### BACKGROUND OF THE INVENTION

This invention relates to an optical information recording medium which records and reproduces an information data signal by irradiating a laser light beam, and, in particular, to a method of manufacturing a ZnS—SiO₂ dielectric layer in a phase change type optical disk.

An optical disk recording system using a laser light beam can record large capacity, and can access with non-contact at high speed. Therefore, an optical disk has been practically used as a large capacity memory in such an optical recording system.

The optical disk is generally classified into a read only type, a recordable type, and a rewritable type. In this case, the read only type has been known as a compact disk or a laser disk. In the recordable type, a user can additionally record an information data signal. In the rewritable type, the user can repeatedly record and erase the information data signal.

The recordable type and the rewritable type have been used as an external recording device or a file for a document and an image.

The rewritable type is further classified into a phase change type optical disk which utilizes phase change of a recording layer, and a magneto-optical disk which utilizes change of a magnetization direction for a vertical magnetization layer.

In the phase change type optical disk, external magnetic field is unnecessary, and has the same reproducing method as the read only type, and over-write of recording information can be readily performed.

From these advantages, it has been expected that the phase change type optical disk is mainly used as the rewritable type optical disk, such as, a rewritable type digital videodisk.

In the recording layer of the phase change type optical disk, chalcogenide based material, such as, GeSbTe base, InSbTe base, InSe base, InTe base, AsTeGe base, TeOx-GeSn base, TeSeSn base, SbSeBi base, BiSeGe base, and AgInSb base is generally used. These recording layers are deposited by the use of a depositing method, such as, an evaporation method and a sputtering method.

Further, the recording layer is in an amorphous state after the deposition. Consequently, an initialization process, which puts an entire recording layer into a crystal state, is carried out to record the data signal for the recording layer.

A recording process is performed by forming the amorphous portion in the crystallized state. Namely, in the phase change type optical disk, the laser light beam of high power is irradiated in accordance with the information data signal to be recorded, and a temperature of the recording layer is locally increased. Thereby, the recording process is conducted by taking place the phase change between the crystal state and the amorphous state in the recording medium.

On the other hand, a reproducing process of the recorded information data signal is carried out by irradiating the laser light beam of relatively low power in comparison with the recording process, and by detecting difference of reflection light intensity.

In the meantime, an erasing process is performed by putting into the crystal state by irradiating the laser light beam having lower power than the recording process. In this case, the temperature of the recording layer falls within the range between a crystallized temperature and a melting point temperature, both inclusive.

Thus, the recording layer of the phase change type optical disk is risen to the melting point temperature or higher by the laser light beam or is risen to the crystallized temperature or higher and the melting point temperature or lower in order to record and erase the information data signal. Herein, it is to be noted that a metal reflection layer also serves as a heat sink.

Meanwhile, repeat recording/reproducing characteristic in the phase change type optical disk is variable in accordance with heat-resistance of the dielectric layers provided at both sides of the recording layer and a layer structure, such as, a layer thickness and a distance from the metal reflection layer, and layer quality.

Conventionally, a ZnS—SiO₂ dielectric film has been used as this kind of dielectric layer. The ZnS—SiO₂ dielectric film is manufactured by depositing by the use of the sputtering method in argon gas atmosphere using a target sintered with mixture of ZnS and SiO₂.

However, argon ions having high energy collide onto a surface of the ZnS—SiO₂ target and a deposited film surface of the ZnS—SiO₂ dielectric film. In consequence, combinations between Si atoms and O atoms (oxygen atoms) of SiO₂ are readily cut. Thereby, dangling bonds of Si are inevitably formed by collision of the argon ions.

Consequently, the ZnS—SiO₂ film is thermally damaged by heat-load due to temperature rising and rapid cooling during the recording/reproducing processes of many times. As a result, diffusion of dielectric substance into the recording layer causes to occur an error, such as, recording impossibility and reduction of reproducing signal amplitude.

Therefore, a variety of suggestions have been conventionally made to improve over-write characteristic of repetition record/reproduction in such a phase change type optical disk.

For example, disclosure has been made about a technique in which SiO₂ quantity contained in a first dielectric layer and a second dielectric layer for sandwiching a recording layer is variable in Japanese Patent Publication No. 2788395.

Further, disclosure has been made about a technique in which a layer thickness of the recording layer falls within the range between 80 nm and 150 nm, and a layer thickness of the dielectric layer of an upper layer falls within the range between 10 nm and 100 nm in Japanese Unexamined Patent Publication (JP-A) No. H08-249723.

Moreover, disclosure has been made about a technique in which an auxiliary layer containing nitrogen is provided between the recording layer and the dielectric layer of an upper layer in Japanese Unexamined Patent Publication (JP-A) No. H06-342529.

In addition, disclosure has been made about a technique in which the ZnS—SiO₂ film is deposited by the use of mixed gas of noble gas, oxygen, and nitrogen in Japanese Unexamined Patent Publication (JP-A) No. H10-222880.

However, none of these suggestions relate to a technique in which formation of dangling bonds of Si appeared in the above-mentioned ZnS—SiO₂ film is suppressed. In consequence, the over-write characteristic caused by the dangling bonds formed in the film has not basically and actually been improved.

### SUMMARY OF THE INVENTION

It is therefore an object of this invention to provide a method of manufacturing a ZnS—SiO₂ dielectric layer in a phase change type optical disk which is capable of improving over-write characteristic.

In a method of manufacturing a dielectric layer of ZnS—SiO₂ for use in a phase change type optical disk according to this invention, a target, which is sintered with mixture of ZnS and SiO₂, is prepared in advance.

Subsequently, the dielectric layer is deposited by the use of a sputtering method in mixed atmosphere of argon gas, oxygen gas, and hydrogen gas.

In this case, the dielectric layer has dangling bonds of Si. The deposition is carried out such that formation of the dangling bonds is suppressed.

Specifically, the dangling bonds are terminated in the deposited dielectric layer by an operation of the mixed atmosphere. Whereby, the dielectric layer becomes chemically stable.

In a method of manufacturing a phase change type optical disk which records, erases, and reproduces an information data signal by changing a phase state through irradiation of a laser light beam according to this invention, a first dielectric layer of ZnS—SiO₂ is deposited on a disk substrate.

Next, a recording layer is deposited on the first dielectric layer.

Subsequently, a second dielectric layer of ZnS—SiO₂ is deposited on the recording layer.

Finally, a metal reflection layer is deposited on the second dielectric layer.

In this event, at least one of the first dielectric layer and the second dielectric layer is deposited by the use of a sputtering method in mixed atmosphere of argon gas, oxygen gas, and hydrogen gas using a target which is sintered with mixture of ZnS and SiO₂.

At least one of the first dielectric layer and the second dielectric layer has dangling bonds of Si. The deposition is carried out such that formation of the dangling bonds is suppressed.

Specifically, the dangling bonds are terminated in the deposited first and second dielectric layers by an operation of the mixed atmosphere. Whereby, the first and second dielectric layers become chemically stable.

In this event, a thickness of the first dielectric layer preferably falls within the range between 80 nm and 300 nm, both inclusive.

A thickness of the second dielectric layer preferably falls within the range between 15 nm and 40 nm, both inclusive.

The recording layer comprises a Ge₂Sb₂Te₅ film which is deposited in atmosphere containing argon gas.

Herein, a thickness of the recording layer preferably falls within the range between 10 nm and 30 nm, both inclusive.

Further, the metal reflection layer comprises an Al—Ti film which is deposited by the use of a sputtering method.

In this case, a thickness of the metal reflection layer falls within the range between 40 nm and 300 nm, both inclusive.

More specifically, mixed gas, in which the hydrogen gas is added into the argon gas and the oxygen gas, is used as the gas atmosphere during the sputtering deposition of the ZnS—SiO₂ layer. Thereby, the dangling bonds of Si in the deposited ZnS—SiO₂ layer are effectively terminated, and the dielectric layer becomes chemically stable.

In consequence, the layer quality is retained to a stable state irrespective of the heat-load due to the thermal hysteresis of the repetition over-write, and the repetition over-write characteristic can be improved.

### BRIEF DESCRIPTION OF THE DRAWINGS

FIG. 1A is a front view of a phase change type optical disk medium according to an embodiment of this invention;

FIG. 1B is a cross sectional view of an A portion in FIG. 1A;

FIG. 1C is an enlarged cross sectional view of a B portion in FIG. 1B;

FIG. 2A is a cross sectional view of a first example;

FIG. 2B is a diagram showing dependency based upon repetition O/W number of a carrier level, a noise level and a C/N ratio;

FIG. 3A is a cross sectional view of a first comparative example;

FIG. 3B is a diagram showing dependency based upon repetition O/W number of a carrier level, a noise level and a C/N ratio;

FIG. 4A is a cross sectional view of a second example;

FIG. 4B is a diagram showing dependency based upon repetition O/W number of a carrier level, a noise level and a C/N ratio;

FIG. 5A is a cross sectional view of a second comparative example; and

FIG. 5B is a diagram showing dependency based upon repetition O/W number of a carrier level, a noise level and a C/N ratio.

### DESCRIPTION OF PREFERRED EMBODIMENT

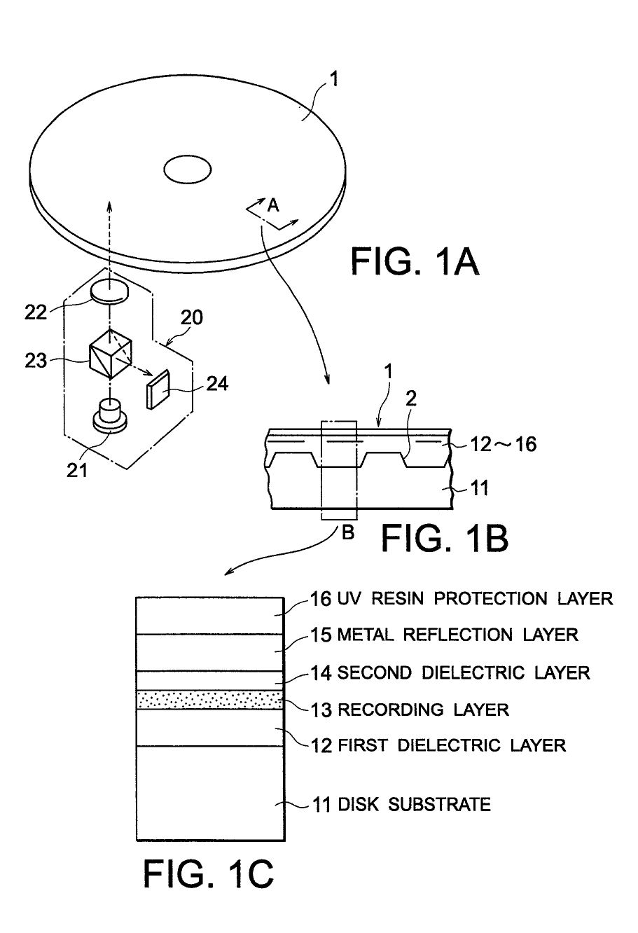

Referring to FIGS. 1A through 1C, description will be made about a phase change type optical disk medium (hereinafter, it may be referred to as an optical disk).

A guide groove 2 is formed to a spiral shape or a concentric circle shape on the basis of a rotation center on a transparent disk substrate 11 of the optical disk 1. In this event, the transparent disk substrate 11 has a thickness of 0.6 mm and a diameter of 120 mm.

A first dielectric layer 12, a recording layer 13, and a second dielectric layer 14 are successively deposited on the disk substrate 11, and further, a metal reflection layer 15 and an UV resin protection layer 16 are formed thereon.

In this case, each of the first dielectric layer 12 and the second dielectric layer 14 is formed by a ZnS—SiO₂ film. The recording layer 13 is formed by Ge₂Sb₂Te₅ film while the metal reflection layer 15 is formed by an Al—Ti film.

The first dielectric layer 12 is deposited by the use of the sputtering method using a target sintered with mixture of ZnS and SiO₂, and is deposited by using mixed gas of argon gas, oxygen gas and hydrogen gas as atmosphere gas during the deposition.

A thickness of the first dielectric layer 12 is 70 nm or more to reduce heat-load against the substrate, and preferably, falls within the range between 80 nm and 300 nm, both inclusive.

Similarly, the ZnS—SiO₂ film as the second dielectric layer 14 is also deposited by the use of the sputtering method using the mixed gas of argon gas, oxygen gas and hydrogen gas as the atmosphere gas during the deposition.

In this event, the thickness of the second dielectric layer 14 is 50 nm or less to effectively release heat for the metal reflection layer 15, and preferably, falls within the range between 15 nm and 40 nm, both inclusive.

In the meantime, the Ge₂Sb₂Te₅ film as the recording layer 13 is deposited in the argon gas atmosphere. The thickness of the recording layer 13 preferably falls within the range between 10 nm and 30 nm, both inclusive.

Further, the Al—Ti film as the metal reflection layer 15 is laminated by the sputtering method. The thickness of the metal reflection layer 15 preferably falls within the range between 40 nm and 300 nm, both inclusive to improve the repetition characteristic and the layer quality.

This reason is explained as follows.

Namely, when the layer thickness of the metal reflection layer 15 is 40 nm or less, sufficient heat-dissipating performance is not obtained, and the repetition characteristic is degraded. On the other hand, the layer thickness of the metal reflection layer 15 is 300 nm or more, the reflection layer is readily peeled.

Although the optical disk 1 having such a structure can be used as a single plate structure illustrated in FIG. 1, the optical disk 1 can be used as both sides specification by laminating the disks of the same specification by the use of adhesives, such as, ultraviolet curing resin on the condition that the side of the metal reflection layer 15 is opposed thereto.

Alternatively, the optical disk 1 can be structured as one side specification by laminating with the substrate, in which the recording layer 13 is not deposited, to enhance rigidity of the optical disk 1.

In such an optical disk 1, the hydrogen gas is contained as the atmosphere gas in addition to the argon gas and the oxygen gas when the ZnS—SiO₂ film is deposited as the first dielectric layer 12 or the second dielectric layer 14. Thereby, the dangling bonds of Si in the deposited ZnS—SiO₂ film are effectively terminated, and the layer quality becomes chemically stable.

Namely, SiO₂, which is deposited on the disk substrate 11 by the sputtering method from the target, forms a random network with Si and O. Under such a circumstance, combinations of the random network are destroyed by adding the hydrogen, and thereby, hydrogen combinations takes place. After the random network is again formed in the next stage, the dangling bonds of SiO₂ are finally terminated.

In consequence, the ZnS—SiO₂ film containing SiO₂, in which the dangling bonds are terminated, becomes stable for heat-load due to temperature rising and rapid cooling during the repetition recording/reproducing processes of many times. Thereby, the over-write characteristic can be improved.

In this case, when an information data signal is recorded for the optical disk 1, a laser light beam from a laser light source 21 provided in an optical head 20 is focused onto the optical disk 1 as an optical spot through a lens optical system 22, as illustrated in FIG. 1.

Further, when the information data signal is reproduced, reflection light beams of the optical spot focused onto the optical disk 1 are separated by a beam splitter 23, and are received by a photo-diode 24.

(First example)

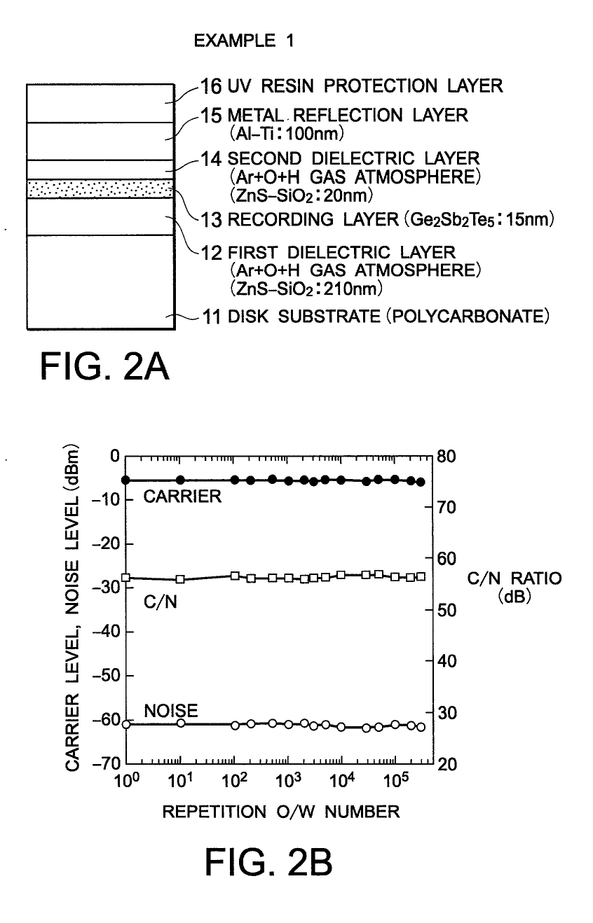

Subsequently, description will be made about a first example with reference to FIG. 2A and FIG. 2B.

As illustrated in FIG. 2A, polycarbonate was used as the disk substrate 1, and the ZnS—SiO₂ film was formed as the first dielectric layer 12. In this event, the atmosphere gas during the deposition was mixed gas containing the argon gas, the oxygen gas and hydrogen gas.

In this case, gas pressure was set to 0.5 Pa, flow rate of the argon gas was set to 20 sccm, flow rate of the oxygen gas was set to 10 sccm, and flow rate of the mixed gas containing the argon and the hydrogen was set to 20 sccm, respectively.

Herein, it is to be noted that the flow rate of the hydrogen gas became 6 sccm because the ratio of the hydrogen was 30%. In this condition, the deposition was carried out under input electric power of 300 W.

In this condition, the layer thickness of the first dielectric layer 12 was equal to 210 nm. Further, the Ge₂Sb₂Te₅ film was deposited to 15 nm as the recording layer 13. The ZnS—SiO₂ layer was deposited to 20 nm as the second dielectric layer 14 under the same deposition condition as the first dielectric layer 12. Moreover, the Al—Ti film was deposited to 100 nm as the metal reflection layer 15.

In this case, each layer was deposited by the use of the sputtering method while the deposition gas atmosphere of the recording layer 13 and the metal reflection layer 15 contained only argon gas.

Thus formed optical disks were laminated by the use of the ultraviolet curing resin. After the recording layer 13 was crystallized (initialized) under line speed of 6 m/s and erasing power of 6 mW, evaluation with respect to the recording/reproducing process was conducted.

In this case, the recording process was performed on the condition that wavelength was 660 nm, NA of an object lens was 0.6, linear velocity was 6 m/s, recording frequency was 2 MHz, duty ratio was 50%, reproducing power was 1.0 mW, erasing power was 4.5 mW ,and recording power was 8.5 mW.

Herein, reducing quantity of C/N for the repetition O/W (over-write) number is illustrated in FIG. 2B. It has been confirmed from FIG. 2B that deterioration does not appear for C/N after the repetition O/W of 300 thousand number, the same value as a C/N initial value is indicated, and the repetition O/W characteristic is excellent.

(First comparative example)

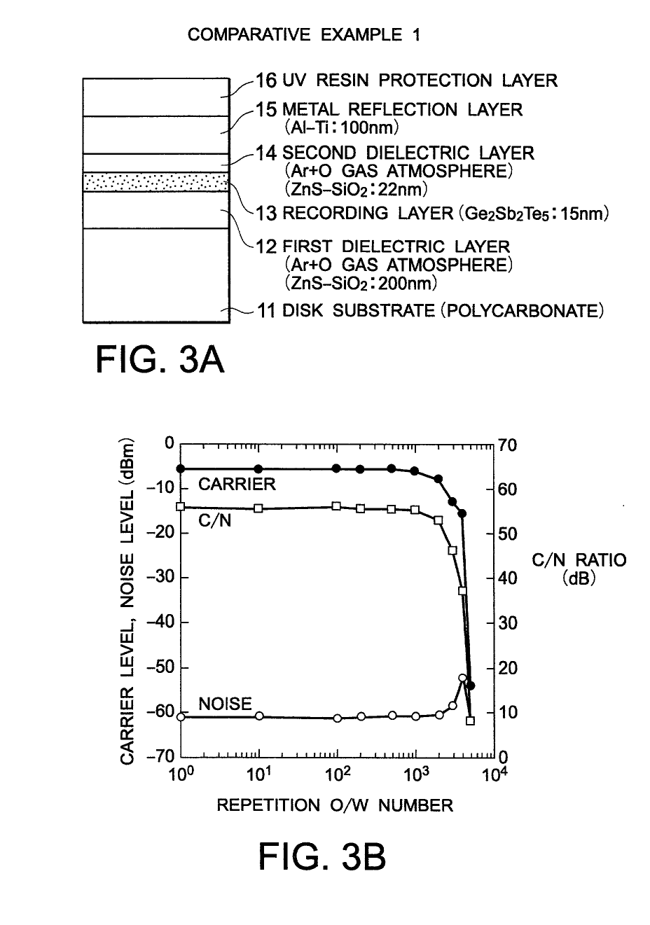

Subsequently, description will be made about a first comparative example with reference to FIG. 3A and FIG. 3B.

As illustrated in FIG. 3A, the polycarbonate was used as the disk substrate 1, and the ZnS—SiO₂ film was used as the first dielectric layer 12. In this event, the atmosphere gas during the deposition was mixed gas of the argon gas and the oxygen gas containing no hydrogen gas.

In this case, the layer thickness of the first dielectric layer 12 was equal to 200 nm. Further, the Ge₂Sb₂Te₅ film was deposited to 15 nm as the recording layer 13.

The ZnS—SiO₂ film was deposited as the second dielectric layer 14 in the mixed gas of the argon gas and the oxygen gas, like the first dielectric layer 12. In the event, the layer thickness of the second dielectric layer 14 was equal to 22 nm.

Further, the Al—Ti film was deposited to 100 nm as the metal reflection layer 15. In this case, each layer was deposited by the use of the sputtering method while the deposition gas atmosphere of the recording layer 13 and the metal reflection layer 15 contained only argon gas.

Thus formed optical disks were laminated by the use of the ultraviolet curing resin. After the recording layer 13 was crystallized (initialized) under line speed of 6 m/s and erasing power of 6 mW, evaluation with respect to the recording/reproducing process was carried out.

In this case, the recording process was performed on the condition that wavelength was 660 nm, NA of an object lens was 0.6, linear velocity was 6 m/s, recording frequency was 2 MHz, duty ratio was 50%, reproducing power was 1.0 mW, erasing power was 4.5 mW ,and recording power was 8.5 mW, like the above-mentioned first example.

Herein, reducing quantity of C/N for the repetition O/W number is illustrated in FIG. 3B. The noise level was increased after the repetition O/W of 3 thousand number, and the recording process became impossible after 5 thousand number.

This is because amplitude of a recording signal was reduced with an increase of a noise level, and the characteristic of the Ge₂Sb₂Te₅ recording layer 13 was changed by diffusion of the dielectric substance.

(Second example)

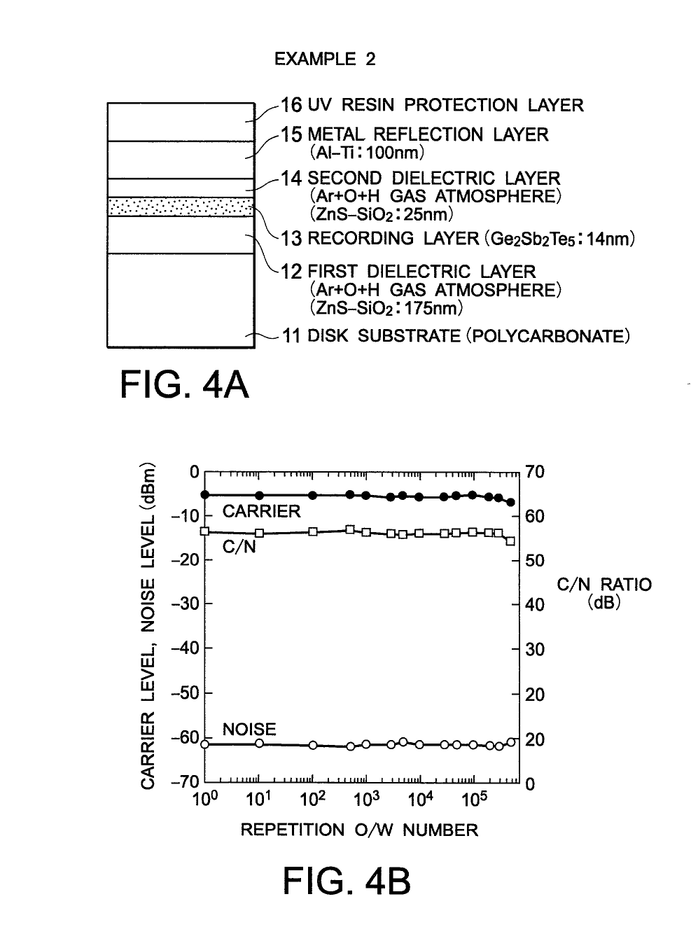

Subsequently, description will be made about a second example with reference to FIG. 4A and FIG. 4B.

As illustrated in FIG. 4A, the polycarbonate was used as the disk substrate 1, and the ZnS—SiO₂ film was formed as the first dielectric layer 12. In this event, the atmosphere gas during the deposition was mixed gas containing the argon gas, the oxygen gas and the hydrogen gas, like the first example.

In this case, the layer thickness of the first dielectric layer 12 was equal to 175 nm. Further, the Ge₂Sb₂Te₅ film was deposited to 14 nm as the recording layer 13. Moreover, the ZnS—SiO₂ film was deposited as the second dielectric layer 14 by using the mixed gas of the argon gas, the oxygen gas, and the hydrogen gas as the atmosphere gas during the deposition, like the above-mentioned first dielectric layer. Herein, the layer thickness was equal to 25 nm.

In addition, the Al—Ti film was deposited to 100 nm as the metal reflection layer 15. In this case, each layer was deposited by the use of the sputtering method. While, the deposition gas atmosphere of the recording layer 13 and the metal reflection layer 15 contained only argon gas.

Thus formed optical disks were laminated by the use of the ultraviolet curing resin. After the recording layer 13 was crystallized (initialized) under line speed of 6 m/s and erasing power of 6 mW, evaluation with respect to the recording/reproducing process was carried out.

In this case, the recording process was performed on the condition that wavelength was 660 nm, NA of an object lens was 0.6, linear velocity is 6 m/s, recording frequency was 2 MHz, duty ratio is 50%, reproducing power was 1.0 mW, erasing power was 4.5 mW ,and recording power was 8.5 mW.

Herein, reducing quantity of C/N for the repetition O/W (over-write) number is illustrated in FIG.4B. It has been confirmed from FIG. 4B that deterioration does not appear for C/N after the repetition O/W of 300 thousand number, the same value as a C/N initial value is indicated, and the repetition O/W characteristic is excellent.

(Second comparative example)

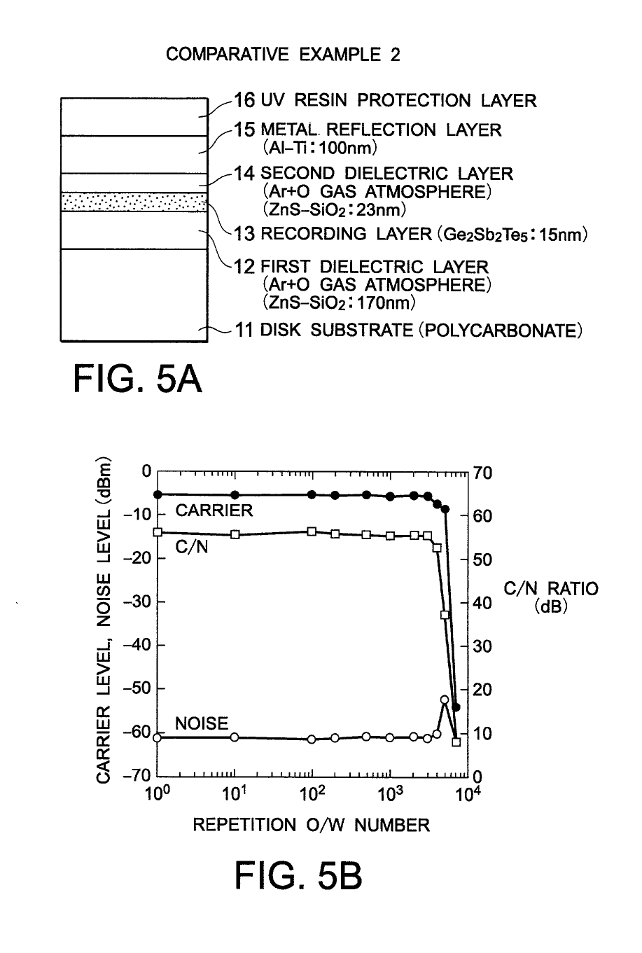

Subsequently, description will be made about a second comparative example with reference to FIG. 5A and FIG.5B.

As illustrated in FIG. 5A, the polycarbonate was used as the disk substrate 1, and the ZnS—SiO₂ film was used as the first dielectric layer 12. In this event, the atmosphere gas during the deposition was mixed gas of the argon gas and the oxygen gas containing no hydrogen gas.

In this case, the layer thickness of the first dielectric layer 12 was equal to 170 nm. Further, the Ge₂Sb₂Te₅ film was deposited to 15 nm as the recording layer 13.

The ZnS—SiO₂ film was deposited as the second dielectric layer 14 in the mixed gas of the argon gas and the oxygen gas, like the first dielectric layer 12. In the event, the layer thickness of the second dielectric layer 14 was equal to 23 nm.

Further, the Al—Ti film was deposited to 100 nm as the metal reflection layer 15. In this case, each layer was deposited by the use of the sputtering method while the deposition gas atmosphere of the recording layer 13 and the metal reflection layer 15 contained only argon gas.

Thus formed optical disks were laminated by the use of the ultraviolet curing resin. After the recording layer 13 was crystallized (initialized) under line speed of 6 m/s and erasing power of 6 mW, evaluation with respect to the recording/reproducing process was performed.

In this case, the recording process was carried out on the condition that wavelength was 660 nm, NA of an object lens was 0.6, linear velocity was 6 m/s, recording frequency was 2 MHz, duty ratio was 50%, reproducing power was 1.0 mW, erasing power was 4.5 mW, and recording power was 8.5 mW, like the above-mentioned second example.

Herein, reducing quantity of C/N for the repetition O/W number is illustrated in FIG.5B. The noise level was increased after the repetition O/W of 5 thousand number, and the recording process became impossible after 7 thousand number.

This is because amplitude of a recording signal was reduced with an increase of a noise level, and the characteristic of the Ge₂Sb₂Te₅ recording layer 13 was changed by diffusion of the dielectric substance. As a result, the repetition O/W characteristic was degraded.

Although the deposition condition or the deposition thickness of the above-mentioned first and second dielectric layer 12,14 has been exemplified, the optical disk 1 having further excellent repetition O/W characteristic can be naturally obtained by suitably changing these conditions.

Further, although the hydrogen is contained in the atmosphere gas during the deposition of the respective first and second dielectric layers 12 and 14 in the above-mentioned embodiment, the hydrogen gas may be mixed into either of the first dielectric layer 12 and the second dielectric layer 14. Thereby, it is possible to improve the repetition O/W characteristic in comparison with the conventional optical disk.

As mentioned before, the mixed gas of the argon gas, the oxygen gas, and the hydrogen gas is used as the deposition gas of the first dielectric layer 12 and the second dielectric layer 14 according to this invention.

Thereby, the dangling bonds due to combination-cutting of Si atoms and the O atoms in SiO₂ of the ZnS—SiO₂ film, which are caused by the corrosion of the argon ions, are effectively terminated. As a result, the dielectric layer can become chemically stable. Further, the phase change type optical disk having the excellent repetition O/W characteristic can be obtained by using this dielectric layer.

What is claimed is:

1. A method of manufacturing a dielectric layer of ZnS—SiO₂ for use in a phase change type optical disk, comprising the steps of:
preparing a target which is sintered with mixture of ZnS and SiO₂; and
depositing the dielectric layer by the use of a sputtering method in mixed atmosphere of argon gas, oxygen gas, and hydrogen gas.

2. A method as claimed in claim 1, wherein:
the dielectric layer has dangling bonds of Si,
the deposition is carried out such that formation of the dangling bonds is suppressed.

3. A method as claimed in claim 2, wherein:
the dangling bonds are terminated in the deposited dielectric layer by an operation of the mixed atmosphere,
whereby, the dielectric layer becoming chemically stable.

4. A method of manufacturing a phase change type optical disk which records, erases, and reproduces an information data signal by changing a phase state through irradiation of a laser light beam, comprising the steps of:
depositing a first dielectric layer of ZnS—SiO₂ on a disk substrate;
depositing a recording layer on the first dielectric layer;
depositing a second dielectric layer of ZnS—SiO₂ on the recording layer; and
depositing a metal reflection layer on the second dielectric layer,
at least one of the first dielectric layer and the second dielectric layer being deposited by the use of a sputtering method in mixed atmosphere of argon gas, oxygen gas, and hydrogen gas using a target which is sintered with mixture of ZnS and SiO₂.

5. A method as claimed in claim 4, wherein:
at least one of the first dielectric layer and the second dielectric layer has dangling bonds of Si,
the deposition is carried out such that formation of the dangling bonds is suppressed.

6. A method as claimed in claim 5, wherein:
the dangling bonds are terminated in the deposited first and second dielectric layers by an operation of the mixed atmosphere,
whereby, the first and second dielectric layers becoming chemically stable.

7. A method as claimed in claim 4, wherein:
a thickness of the first dielectric layer falls within the range between 80 nm and 300 nm, both inclusive.

8. A method as claimed in claim 4, wherein:
a thickness of the second dielectric layer falls within the range between 15 nm and 40 nm, both inclusive.

9. A method as claimed in claim 4, wherein:
the recording layer comprises a Ge₂Sb₂Te₅ film which is deposited in atmosphere containing argon gas.

10. A method as claimed in claim 9, wherein:
a thickness of the recording layer falls within the range between 10 nm and 30 nm, both inclusive.

11. A method as claimed in claim 4, wherein:
the metal reflection layer comprises an Al—Ti film which is deposited by the use of a sputtering method.

12. A method as claimed in claim 11, wherein:
a thickness of the metal reflection layer falls within the range between 40 nm and 300 nm, both inclusive.

13. A phase change type optical disk which records, erases, and reproduces an information signal by changing a phase state through irradiation of a laser light beam, comprising:
a first dielectric layer of ZnS—SiO₂ on a disk substrate;
a recording layer on the first dielectric layer;
a second dielectric layer of ZnS—SiO₂ on the recording layer; and
a metal reflection layer on the second dielectric layer,
the dangling bonds of Si being terminated in at least one of the first dielectric and the second dielectric layer,
whereby, the first and second dielectric layers becoming chemically stable.

14. A disk as claimed in claim 13, wherein:
a thickness of the first dielectric layer falls within the range between 80 nm and 300 nm, both inclusive.

15. A disk as claimed in claim 13, wherein:
a thickness of the second dielectric layer falls within the range between 15 nm and 40 nm, both inclusive.

16. A disk as claimed in claim 13, wherein:
the recording layer comprises a Ge₂Sb₂Te₅ film.

17. A disk as claimed in claim 13, wherein:
a thickness of the recording layer falls within the range between 10 nm and 30 nm, both inclusive.

18. A disk as claimed in claim 13, wherein:
the metal reflection layer comprises an Al—Ti film.

19. A disk as claimed in claim 13, wherein:
a thickness of the metal reflection layer falls within the range between 40 nm and 300 nm, both inclusive.
